(19) United States
(12) Patent Application Publication
(10) Pub. No.: US 2026/0243810 A1
(43) Pub. Date: Aug. 20, 2026

(54) MEASURING AND CALIBRATING THE CHARACTERISTIC COEFFICIENT OF A ROOT MEAN SQUARE (RMS) POWER DETECTOR

(71) Applicant: STMicroelectronics International N.V., Geneva (CH)

(72) Inventors: Pravesh Kumar SAINI, Greater Noida (UP) (IN); Mauro GIACOMINI, Bergamo (BG) (IT); Anil NAGENDRA, Bengaluru (IN)

(73) Assignee: STMicroelectronics International N.V., Geneva (CH)

(21) Appl. No.: 19/057,438

(22) Filed: Feb. 19, 2025

(51) Int. Cl. G01R 29/08; G01R 19/02; G01R 19/22; G01R 35/00

(52) U.S. Cl. CPC G01R 29/0892; G01R 19/02; G01R 19/22; G01R 35/005

(57) ABSTRACT

A power detector circuit includes a squarer circuit formed by at least one MOSFET device with a gate, a source and a drain. When configured in a normal operating mode, an RF signal and a gate bias signal are applied to the gate of the at least one MOSFET device and a drain current at the drain of the MOSFET device is indicative of power of the RF signal. Conversely, when configured in a calibration mode, a DC test signal and the gate bias signal are applied to the gate of the at least one MOSFET device and the drain current at the drain of the MOSFET device is indicative of power of the DC test signal. The drain current is filtered and converted to analog voltage. The analog voltage is converted to a digital code that is processed to determine a characteristic code of the power detector circuit.

### TECHNICAL FIELD

The present invention generally relates to a root mean square (RMS) power detector for use, for example, in a radio frequency (RF) analog gain control (AGC) loop and, in particular, to the measurement and calibration of a characteristic coefficient of the RMS power detector.

### BACKGROUND

Reference is made to FIG. 1 which shows a block diagram of a radio frequency (RF) receiver including an automatic gain control (AGC) loop. An RF antenna 10 is coupled to the input of a low noise amplifier (LNA) circuit 12 having gain which is controllable in response to control signaling 14 generated by an AGC logic circuit 16. An RF signal received by the antenna 10 is output from the LNA circuit 12. The RF signal is processed through an RF signal processing chain circuit 18 having one or more signal processing functions (for example, signal amplification, signal mixing, etc.) having gains which are also controllable in response to the control signaling 14 generated by the AGC logic circuit 16. An intermediate frequency or baseband frequency signal 20 is output from the RF signal processing chain circuit 18 to a digital signal processor circuit (DSP) for further processing operations as known to those skilled in the art. A power detector circuit 30 receives the RF signal output from the LNA circuit 12, measures root mean square (RMS) power of the RF signal, and generates a digital code signal indicative of the measured RMS power for application to the AGC logic circuit 16. The control signaling 14 is generated by the AGC logic circuit 16 in response to, at least, the digital code signal output by the power detector circuit 30 (as well as control signals generated, for example, by the digital signal processor circuit).

The power detector circuit 30 includes a squarer circuit 32 which exploits the square law characteristic of metal oxide semiconductor field effect transistor (MOSFET) devices to convert the RMS power of the RF signal to an output current signal 34 having a current magnitude corresponding to the measured RMS power level. A transimpedance amplifier (TIA) circuit 36 (with a filter in its feedback) converts the output current signal 34 to a corresponding analog output voltage signal 38 indicative of the measured RMS power. The analog output voltage signal 38 is then digitized by an analog to digital converter (ADC) circuit 40 which outputs the digital code signal to the AGC logic circuit 16.

The characteristic coefficient (CC) of the power conversion operation performed by the power detector circuit 30 (i.e., converting the RMS power of the RF signal to the digital code signal) is dependent on the characteristics of the MOSFET devices and resistors used in the power detector circuit 30. These characteristics, however, vary with process and temperature. Thus, there is a need to calibrate the characteristic coefficient (i.e., gain) of the power detector circuit 30 to ensure that the signal swing remains constant irrespective of the strength (weak or strong) of the incoming RF signal.

### SUMMARY

In an embodiment, a root mean square (RMS) power detector circuit comprises: a first input configured to receive a radio frequency (RF) signal; a second input configured to receive a gate bias signal; a third input configured to receive a direct current (DC) test signal; a squarer circuit comprising a MOSFET device with a gate, a source and a drain; wherein, in a normal operating mode, the RF signal and the gate bias signal are applied to the gate of the MOSFET device and a drain current at the drain of the MOSFET device is indicative of power of the RF signal; and wherein, in a calibration mode, the DC test signal and the gate bias signal are applied to the gate of the MOSFET device and the drain current at the drain of the MOSFET device is indicative of power of the DC test signal.

In an embodiment, a radio frequency (RF) receiver comprises: a low noise amplifier (LNA) circuit coupled to an antenna; an RF signal processing chain coupled to receive an RF signal output from the LNA circuit; an automatic gain control (AGC) circuit configured to control signaling for controlling gain at the LNA circuit and in the RF signal processing chain in response to a digital code indicative of RF power; and a power detector circuit coupled to receive then RF signal output from the LNA circuit. The power detector circuit comprises: a squarer circuit comprising a MOSFET device with a gate, a source and a drain; wherein, in a normal operating mode, the RF signal and a gate bias signal are applied to the gate of the MOSFET device and a drain current at the drain of the MOSFET device is indicative of power of the RF signal; wherein, in a calibration mode, a DC test signal and the gate bias signal are applied to the gate of the MOSFET device and the drain current at the drain of the MOSFET device is indicative of power of the DC test signal; a transimpedance amplifier (TIA) circuit configured to convert the drain current to an analog voltage; and an analog to digital converter (ADC) circuit configured to convert the analog voltage to the digital code for input to the AGC circuit.

In an embodiment, a method comprises: in a normal operating mode, applying an RF signal and a gate bias signal to a gate of a MOSFET device within a root mean square (RMS) power detector circuit and generating a drain current indicative of power of the RF signal; and in a calibration mode, applying a DC test signal and the gate bias signal to the gate of the MOSFET device and generating the drain current indicative of power of the DC test signal.

In an embodiment, a power detector circuit comprises: a squarer circuit, comprising: a first differential pair of MOSFET devices having gate terminals biased by a gate bias signal and configured to receive an input signal, said first differential pair of MOSFET devices configured to generate a sensing current indicative of power of the input signal; and a second differential pair of MOSFET devices having gate terminals biased by the gate bias signal, said second differential pair of MOSFET devices configured to generate a reference current; wherein, in a normal operating mode, the input signal is an RF signal; and wherein, in a calibration operating mode, the input signal is a DC test signal. The power detector circuit further comprises: a transimpedance amplifier circuit configured to convert a difference between the sensing current and the reference current to an analog voltage; and an analog to digital converter circuit configured to convert the analog voltage to a digital code indicative of power of the RF signal, when in the normal operating mode, and indicative of power of the DC test signal, when in the calibration operating mode.

### BRIEF DESCRIPTION OF THE DRAWINGS

For a better understanding of the embodiments, reference will now be made by way of example only to the accompanying figures in which:

FIG. 1 is a block diagram of a radio frequency (RF) receiver including an automatic gain control (AGC) loop;

FIG. 2 is a block diagram of an RF receiver including an AGC loop with a first embodiment of a calibration function for a characteristic coefficient of the AGC power detector;

FIG. 3 is a block diagram of an RF receiver including an AGC loop with a second embodiment of a calibration function for a characteristic coefficient of the AGC power detector;

FIG. 4 shows an example circuit for implementing the squarer circuit and transimpedance amplifier circuit of the power detector in FIG. 3;

FIG. 5 is a block diagram of an enhancement to the RF receiver of FIG. 3; and

FIG. 6 shows an example circuit for implementing the squarer circuit and transimpedance amplifier circuit of the power detector in FIG. 3 while including a dynamic range adjustment shifting circuit.

### DETAILED DESCRIPTION

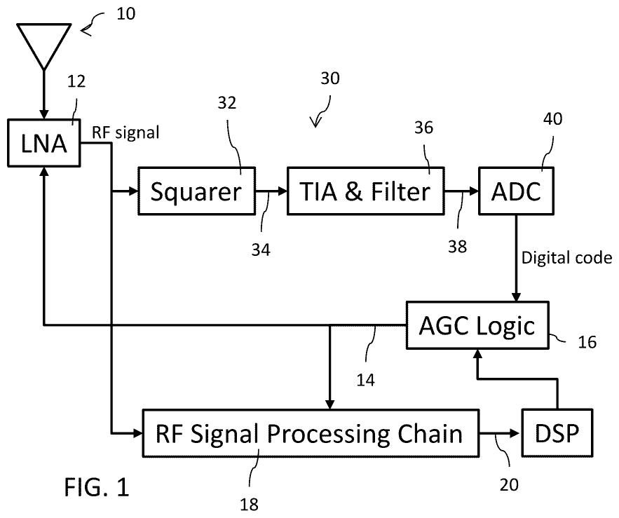

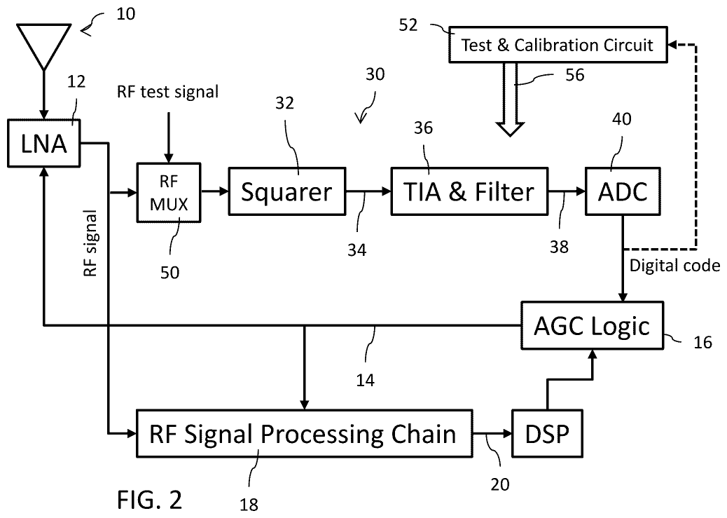

Reference is made to FIG. 2 where like references refer to same or similar components as shown in FIG. 1. The implementation of FIG. 2 differs from the implementation of FIG. 1 in the further inclusion of a characteristic coefficient calibration functionality. An RF multiplexer (Mux) circuit 50 includes a first input coupled to receive the RF signal from the LNA circuit 12 and a second input coupled to receive an RF test signal having a controlled amplitude and frequency. During a calibration mode of operation, the RF Mux circuit 50 switches to select the RF test signal received at the second input, in place of the RF signal from the antenna and LNA circuit 12, for application to the power detector circuit 30 at the input of the squarer circuit 32. This RF test signal may, for example, be generated off-chip and applied to an input test pad of the integrated circuit device. A test and calibration circuit 52 controls the switching of the RF Mux circuit 50 during calibration mode. The digital code generated by the ADC converter circuit 40 at the output of the power detector circuit 30 is received by the test and calibration circuit 52, which can process the generated digital code, based on the known amplitude and frequency of the RF test signal during calibration mode, to determine the gain (i.e., characteristic coefficient) of the power detector circuit 30. The test and calibration circuit 52 can then generate control signaling 56 for application to the power detector circuit 30 to adjust the characteristic coefficient and thus compensate for process and temperature variation.

There are a number of drawbacks associated with the calibration solution shown in FIG. 2 including: application of the known RF test signal is difficult and time consuming; and the required inclusion of the RF Mux circuit 50 in the signal path to the squarer circuit 32 introduces a compromise in accuracy.

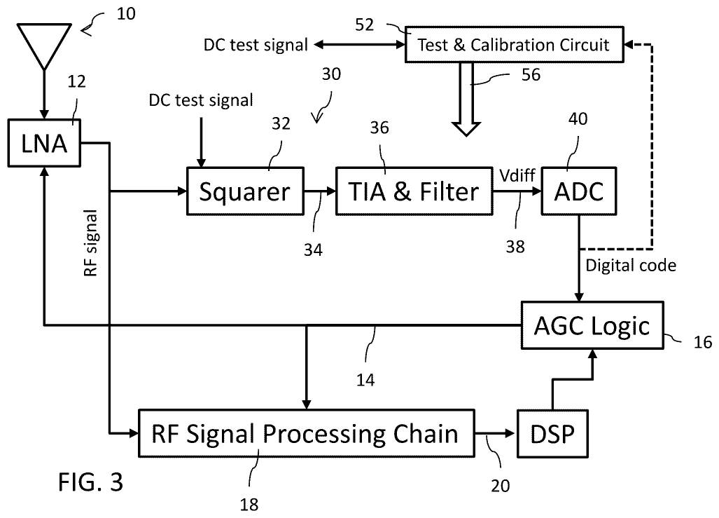

Reference is made to FIG. 3 where like references refer to same or similar components as shown in FIG. 1. The implementation of FIG. 3 differs from the implementation of FIG. 1 in the further inclusion of a characteristic coefficient calibration functionality. A direct current (DC) test signal having a variably controlled amplitude is applied during a calibration mode of operation, without the RF signal received from the antenna through the LNA circuit 12 being applied, to the power detector circuit 30 at the input of the squarer circuit 22. This DC test signal may, for example, be generated off-chip and applied to an input test pad of the integrated circuit device. Alternatively, the DC test signal may be generated on-chip from a reference voltage generator circuit (for example, based on a bandgap voltage). A test and calibration circuit 52 may be used to control switching of voltage level for the variably controlled amplitude of the DC test signal to one or more selected DC voltage values. The digital code generated by the ADC converter circuit 40 at the output of the power detector circuit 30 in response to each applied voltage level for the DC text signal is received by the test and calibration circuit 52, which can process the generated digital code, based on the known amplitude of the DC test signal during calibration mode, to determine the gain (i.e., characteristic coefficient) of the power detector circuit 30. The test and calibration circuit 52 can then generate control signaling 56 for application to the power detector circuit 30 to adjust the characteristic coefficient and thus compensate for process and temperature variation. The test and calibration circuit 52 may further include voltage sensing circuitry, and an analog to digital conversion functionality, to accurately measure each voltage level for the variably controlled amplitude of the DC test signal.

The generation and management of the voltage levels for the variably controlled amplitude of the DC test signal is a much simpler and accurate process than the use of the RF test signal as shown in the FIG. 2 calibration solution.

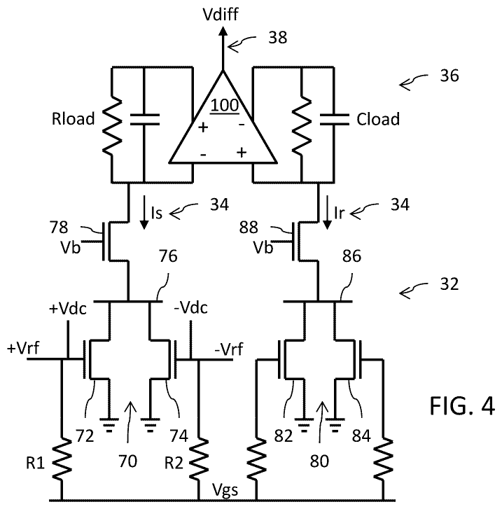

Reference is now made to FIG. 4 which shows a circuit diagram for the squarer circuit 32 and TIA amplifier 36. The squarer circuit 32 includes a first differential input stage 70 comprising first and second metal oxide semiconductor field effect transistor (MOSFET) devices 72, 74. The second MOSFET device 74 is identical to the first MOSFET device 72. The first and second MOSFET devices 72 and 74 are gate biased through biasing resistor network R1, R2 in the same condition with a bias voltage Vgs. A differential input voltage Vin is also applied to the gates of the first and second MOSFET devices 72 and 74 (such that the gate of the first MOSFET device 72 receives Vgs+Vin and the gate of the second MOSFET device 74 receives Vgs-Vin). The differential RF signal Vrf is applied as the differential voltage Vin when configured in normal operating mode. Conversely, the differential DC test signal Vdc is applied as the differential voltage Vin when configured in calibration mode. The source terminals of the MOSFET devices 72 and 74 are coupled to a reference voltage node (for example, ground). The drains of the MOSFET devices 72 and 74 are coupled to provide drain current to a common node 76. A first output (sense) current Is, comprising a differential component of the output current signal 34, flows as drain current through a third MOSFET device 78, connected in cascode and biased by a bias voltage Vb, to the common node 76.

The squarer circuit 32 further includes a second differential input stage 90 comprising fourth and fifth MOSFET devices 82, 84. The fifth MOSFET device 84 is identical to the fourth MOSFET device 82. The fourth and fifth MOSFET devices 82 and 84 are gate biased through a resistor network in the same condition with the bias voltage Vgs. The source terminals of the MOSFET devices 82 and 84 are coupled to the reference voltage node (for example, ground). The drains of the MOSFET devices 82 and 84 are coupled to provide drain current to a common node 86. A second output (reference) current Ir, comprising a further differential component of the output current signal 34, flows as drain current through a sixth MOSFET device 88, in cascode and biased by the bias voltage Vb, to the common node 86.

In a preferred implementation, the MOSFET devices 72, 72, 82, 84 are matching devices.

In a normal operating mode of the power detector circuit 20, the RF signal Vrf in differential signaling is applied as the input signal Vin (such that Vin=Vrf/2). Conversely, when in calibration mode, the voltages for the variably controlled amplitude of the DC test signal Vdc in differential signaling are applied as the input signal Vin (such that Vin=Vdc/2).

The drain current of the first MOSFET device 72 is given by the following:

$${I}_{72} = \frac{K}{2} \frac{W}{L} {( Vgs + Vin - Vt )}^{2}$$

$${I}_{72} = \frac{K}{2} \frac{W}{L} ( {Vgs}^{2} + {Vin}^{2} - {Vt}^{2} + 2 VgsVin - 2 VgsVt - 2 VinVt )$$

The drain current of the second MOSFET device 74 is given by the following:

$${I}_{74} = \frac{K}{2} \frac{W}{L} {( Vgs - Vin - Vt )}^{2}$$

$${I}_{74} = \frac{K}{2} \frac{W}{L} ( {Vgs}^{2} + {Vin}^{2} - {Vt}^{2} + 2 VgsVin - 2 VgsVt + 2 VinVt )$$

Where: K=μₙCₒₓ, and un is average electron mobility, Cₒₓ is gate oxide capacitance per unit area, Vt is threshold voltage, W is transistor gate width, L is transistor gate length, Vgs is the DC biasing voltage for the transistors.

The drain current of the fourth MOSFET device 82 is given by the following:

$${I}_{82} = \frac{K}{2} \frac{W}{L} {( Vgs - Vt )}^{2}$$

$${I}_{82} = \frac{K}{2} \frac{W}{L} ( {Vgs}^{2} - 2 VgsVt + {Vt}^{2} )$$

The drain current of the fifth MOSFET device 84 is given by the following:

$${I}_{84} = \frac{K}{2} \frac{W}{L} {( Vgs - Vt )}^{2}$$

$${I}_{84} = \frac{K}{2} \frac{W}{L} ( {Vgs}^{2} - 2 VgsVt + {Vt}^{2} )$$

When configured in normal operating mode, where

$$Vin = \frac{Vrf}{2} = \frac{Vi}{2} cos ( ω t ) ;$$

with Vi being the amplitude of the RF signal and ω the frequency of the RF signal, the first output (sense) current Is is:

$$Is = {I}_{72} + {I}_{74}$$

$$Is = \frac{K}{2} \frac{W}{L} ( {Vgs}^{2} + {( \frac{Vi}{2} cos ( ω t ) )}^{2} + {Vt}^{2} + 2 Vgs ( \frac{Vi}{2} cos ( ω t ) ) - 2 VgsVt - 2 ( \frac{Vi}{2} cos ( ω t ) ) Vt ) + \frac{K}{2} \frac{W}{L} ( {Vgs}^{2} + {( \frac{Vi}{2} cos ( ω t ) )}^{2} + {Vt}^{2} - 2 Vgs ( \frac{Vi}{2} cos ( ω t ) ) - 2 VgsVt + 2 ( \frac{Vi}{2} cos ( ω t ) ) Vt )$$

$$Is = \frac{K}{2} \frac{W}{L} ( ( {Vgs}^{2} + {( \frac{Vi}{2} cos ( ω t ) )}^{2} + {Vt}^{2} + Vgs ( Vi cos ( ω t ) ) - 2 VgsVt - ( Vi cos ( ω t ) ) Vt ) + ( {Vgs}^{2} + {( \frac{Vi}{2} cos ( ω t ) )}^{2} + {Vt}^{2} - Vgs ( Vi cos ( ω t ) ) - 2 VgsVt + ( Vi cos ( ω t ) ) Vt ) )$$

$$Is = \frac{K}{2} \frac{W}{L} ( 2 {Vgs}^{2} + 2 {( \frac{Vi}{2} cos ( ω t ) )}^{2} + 2 {Vt}^{2} - 4 VgsVt )$$

Furthermore, in normal operating mode, the second output current Ir is:

$$Ir = {I}_{82} + {I}_{84}$$

$$Ir = \frac{K}{2} \frac{W}{L} {( Vgs - Vt )}^{2} + \frac{K}{2} \frac{W}{L} {( Vgs - Vt )}^{2} = \frac{KW}{L} {( Vgs - Vt )}^{2}$$

$$Ir = \frac{KW}{L} ( {Vgs}^{2} - 2 VgsVt + {Vt}^{2} ) = \frac{K}{2} \frac{W}{L} ( 2 {Vgs}^{2} - 4 VgsVt + 2 {Vt}^{2} )$$

Conversely, when configured in calibration mode, where

$$Vin = \frac{Vdc}{2} ,$$

with Vdc being the magnitude of the DC test signal, then first output current Is is:

$$Is = {I}_{72} + {I}_{74}$$

$$Is = \frac{K}{2} \frac{W}{L} ( {Vgs}^{2} + {( \frac{Vdc}{2} )}^{2} + {Vt}^{2} + 2 Vgs ( \frac{Vdc}{2} ) - 2 VgsVt - 2 ( \frac{Vdc}{2} ) Vt ) + \frac{K}{2} \frac{W}{L} ( {Vgs}^{2} + {( \frac{Vdc}{2} )}^{2} + {Vt}^{2} - 2 Vgs ( \frac{Vdc}{2} ) - 2 VgsVt + 2 ( \frac{Vdc}{2} ) Vt )$$

$$Is = \frac{K}{2} \frac{W}{L} ( ( {Vgs}^{2} + {( \frac{Vdc}{2} )}^{2} + {Vt}^{2} + Vgs ( \frac{Vdc}{2} ) - 2 VgsVt - ( \frac{Vdc}{2} ) Vt ) + ( {Vgs}^{2} + {( \frac{Vdc}{2} )}^{2} + {Vt}^{2} - 2 Vgs ( \frac{Vdc}{2} ) - 2 VgsVt + 2 ( \frac{Vdc}{2} ) Vt ) )$$

$$Is = \frac{K}{2} \frac{W}{L} ( 2 {Vgs}^{2} + 2 {( \frac{Vdc}{2} )}^{2} + 2 {Vt}^{2} - 4 VgsVt )$$

Furthermore, in calibration operating mode, the second output current Ir is:

$$Ir = {I}_{82} + {I}_{84}$$

$$Ir = \frac{K}{2} \frac{W}{L} {( Vgs - Vt )}^{2} + \frac{K}{2} \frac{W}{L} {( Vgs - Vt )}^{2} = \frac{KW}{L} {( Vgs - Vt )}^{2}$$

$$Ir = \frac{KW}{L} ( {Vgs}^{2} - 2 VgsVt + {Vt}^{2} ) = \frac{K}{2} \frac{W}{L} ( 2 {Vgs}^{2} - 4 VgsVt + 2 {Vt}^{2} )$$

The TIA circuit 36 includes a fully differential operational amplifier 100 having an inverting input coupled to the drain of the third MOSFET device 78 (in a sense branch of the squarer circuit 32) and a non-inverting input coupled to the drain of the sixth MOSFET device 88 (in a reference branch of the squarer circuit 32). Coupled in feedback between the non-inverting output and inverting input of the operational amplifier 100 is a first parallel resistor-capacitor (RC) circuit including load resistor Rload and load capacitor Cload. Coupled in feedback between the inverting output and non-inverting input of the operational amplifier 100 is a second parallel resistor-capacitor (RC) circuit including load resistor Rload and load capacitor Cload. The TIA circuit 36 (with the low pass filter in its feedback formed by the first and second parallel RC circuits) converts the difference between the first and second output currents Is, Ir generated by the squarer circuit 32 to a corresponding output voltage signal (Vdiff) 38.

The input current difference Idiff to the TIA circuit 36 in normal operating mode is:

$$Idiff = Is - Ir$$

$$Idiff = \frac{K}{2} \frac{W}{L} ( 2 {Vgs}^{2} + 2 {( \frac{Vi}{2} cos ( ω t ) )}^{2} + 2 {Vt}^{2} - 4 VgsVt ) - ( \frac{K}{2} \frac{W}{L} ( 2 {Vgs}^{2} - 4 VgsVt + 2 {Vt}^{2} ) )$$

$$Idiff = \frac{K}{2} \frac{W}{L} ( 2 {( \frac{{Vi}^{2}}{4} cos ( ω t ) )}^{2} ) = \frac{K}{2} \frac{W}{L} ( 2 ( \frac{{Vi}^{2}}{4} ) {cos}^{2} ( ω t ) )$$

Using the trigonometric identity:

$${cos}^{2} ( x ) = \frac{1 - cos ( 2 x )}{2}$$

$$Idiff = \frac{K}{2} \frac{W}{L} ( \frac{{Vi}^{2}}{4} - {Vi}^{2} cos ( 2 ω t ) )$$

In normal operating mode, the output voltage signal (Vdiff) 38 is:

$$Vdiff = Rload ( Idiff )$$

The capacitors Cload filter out the fundamental and harmonic frequency components (for example, any components based on the cos (2ωt) term) of the RF signal which are greater than the filter cut-off frequency, and thus:

$$Vdiff = Rload ( \frac{KW}{8 L} {Vi}^{2} )$$

The ADC circuit 40 converts the analog signal voltage Vdiff to generate the digital code output indicative of RF power.

The input current difference Idiff to the TIA circuit 36 in the calibration mode is:

$$Idiff = Is - Ir$$

$$Idiff = ( \frac{K}{2} \frac{W}{L} ( 2 {Vgs}^{2} + 2 {( \frac{Vdc}{2} )}^{2} + 2 {Vt}^{2} - 4 VgsVt ) ) - ( \frac{K}{2} \frac{W}{L} ( 2 {Vgs}^{2} - 4 VgsVt + 2 {Vt}^{2} ) )$$

$$Idiff = \frac{K}{2} \frac{W}{L} ( ( 2 {Vgs}^{2} + 2 {( \frac{Vdc}{2} )}^{2} + 2 {Vt}^{2} - 4 VgsVt ) - ( 2 {Vgs}^{2} - 4 VgsVt + 2 {Vt}^{2} ) )$$

$$Idiff = \frac{K}{2} \frac{W}{L} ( 2 {( \frac{Vdc}{2} )}^{2} ) = \frac{K}{2} \frac{W}{L} ( 2 ( \frac{{Vdc}^{2}}{4} ) )$$

In calibration operating mode, the output voltage signal (Vdiff) 38 is:

$$Vdiff = Rload ( \frac{KW}{4 L} {Vdc}^{2} )$$

The ADC circuit 40 converts the analog signal voltage Vdiff to generate the digital code output indicative of the DC voltage level of the DC test signal having the voltage level Vdc.

In calibration mode, the ADC output digital code (Ac) generated in response to the applied DC test signal (at the voltage level Vdc) is given by:

$${A}_{c} = {CC}_{act} * {Vdc}^{2}$$

Where: CC_{act} is the actual characteristic coefficient of the power detector circuit 30.

It is noted, however, that there will be a residual offset in the signal processing chain of the power detector circuit 30 and/or a measurement offset will be present. Calculation of the characteristic coefficient with accuracy thus cannot be made using only a single voltage level for the DC test signal Vdc. Another variable needs to the added to accommodate the offset. The equation for the generated ADC output digital code (Ac) is accordingly:

$${A}_{c} = {CC}_{act} * {Vdc}^{2} + {A}_{o}$$

Where: Aₒ accounts for the included offset.

In view of the foregoing, there are two unknowns (i.e., the actual characteristic coefficient CC_{act} and the offset Aₒ). Because of this, the calibration operation must apply the DC test signal Vdc with two different DC voltage levels, and from the digital codes generated by the ADC circuit in response to the two distinct DC test voltages, the actual characteristic coefficient of the power detector circuit 30 can be calculated by the test and calibration circuit 52.

The squarer circuit 32, as shown in FIG. 4, includes a resistor network for applying the bias voltage Vgs to the gate terminals of the MOSFET devices 72, 74, 82, 84. Ideally, the resistance values R1 and R2 of the biasing resistor network coupled to the MOSFET devices 72, 74 and 82, 84 should be equal. However, resistance mismatch can occur, and this introduces a DC test voltage Vdc dependent common mode error to the operation of the squarer circuit 32. The common mode voltage (Vcmr) at the gates of the MOSFET devices 82, 84 in the reference branch of the squarer circuit 32 generating the current Ir may then be offset from the common mode voltage (Vcm) at the gates of the MOSFET devices 72, 74 in the sensing branch of the squarer circuit 32 generating the current Is, such that:

$$Vcmr = Vcm + \frac{Vdc}{2} ( ( R 2 - R 1 ) / ( R 2 + R 1 ) )$$

In the calibration mode, the operation to calibrate based on two distinct DC test voltages, as discussed above, works well when R1=R2. In the case of resistance mismatch (R1/R2), however, the calibration operation must apply the DC test signal Vdc with three different DC voltage levels, and from the digital codes generated by the ADC circuit in response to the three distinct DC test voltages, the actual characteristic coefficient of the power detector circuit 30 can be calculated by the test and calibration circuit 52.

In support of the foregoing, where there is a resistance mismatch in the DC bias resistors R1, R2, the difference in current is:

$$Idiff = K ( 2 * Vgs * Vdc * Ar * {Vdc}^{2} * ( {Ar}^{2} + \frac{1}{4} ) )$$

Where:

$$Ar = \frac{( R 2 - R 1 )}{2 ( R 1 + R 2 )}$$

So, in calibration mode, the current Is in the sensing branch is:

$$\begin{matrix}Is = \frac{k}{2} {( Vcm + Vdc * Ar + \frac{Vdc}{2} - Vt )}^{2} + \frac{k}{2} {( Vcm + Vdc * Ar - \frac{Vdc}{2} - Vt )}^{2} \\ Vgs = ( Vcm - Vt ) \\ Is = \frac{k}{2} {( Vgs + Vdc * Ar + \frac{Vdc}{2} )}^{2} + \frac{k}{2} {( Vgs + Vdc * Ar - \frac{V d c}{2} )}^{2} \\ Is = \frac{k}{2} ( {( Vgs + Vdc * Ar )}^{2} + \frac{{Vdc}^{2}}{4} ) + \frac{k}{2} ( {( Vgs + Vdc * Ar )}^{2} + \frac{{Vdc}^{2}}{4} ) \\ Is = K ( {( Vgs + Vdc * Ar )}^{2} + \frac{{Vdc}^{2}}{4} ) \\ Is = K ( {Vgs}^{2} + {( Vdc * Ar )}^{2} + 2 Vgs * Vdc * Ar + \frac{{Vdc}^{2}}{4} )\end{matrix}$$

For the current Ir in the reference branch:

$$Ir = K * {Vgs}^{2}$$

The difference in current Idiff is then:

$$\begin{matrix}Idiff = Is - Ir \\ Idiff = K * ( {( Vdc * Ar )}^{2} + ( 2 Vgs * Vdc * Ar ) + \frac{{Vdc}^{2}}{4} ) \\ Idiff = K * ( 2 Vgs * Vdc * Ar + \frac{{Vdc}^{2}}{4} + ( Vdc + {Ar}^{2} ) ) \\ Idiff = K * ( 2 Vgs * Vdc * Ar + {Vdc}^{2} * ( {Ar}^{2} + \frac{1}{4} ) )\end{matrix}$$

Due to there being limited resistor mismatch in integrated circuit implementations of the biasing circuitry, it can be assumed that

$${Ar}^{2} ≪ \frac{1}{4}$$

As a result, the equation simplifies to:

$$\begin{matrix}Idiff = K * ( 2 Vgs * Vdc * Ar + \frac{{Vdc}^{2}}{4} ) \\ Idiff = K * \frac{{Vdc}^{2}}{4} + ( 2 * K * Vgs * Vdc * Ar )\end{matrix}$$

In calibration mode, the ADC output digital code (Ac) generated in response to the applied DC test signal (at the voltage level Vdc) is given by:

$${A}_{c} = {CC}_{act} * {Vdc}^{2} + CCoff * Vdc + {A}_{o}$$

Where CCoff*Vdc accounts for the included offset due to biasing resistance mismatch.

As previously noted, in the case of resistance mismatch (R1/R2) the calibration operation applies the DC test signal Vdc with three different DC voltage levels and processes the corresponding ADC circuit output digital codes to calculate the actual characteristic coefficient of the power detector circuit 30.

Before applying the different DC voltage levels for the DC test signal Vdc in calibration mode, it is necessary for the test and calibration circuit 52 to know the DC voltage levels. This can be accomplished by converting the DC voltage levels using an analog to digital converter or measuring the DC voltage levels using analog test circuitry (for example, within the test and calibration circuit 52).

The ADC output digital code (Ac) corresponding to an applied DC voltage level Vdc, when the TIA circuit 36 is bypassed, is given by:

$${A}_{c} = 512 * ( 1 + \frac{Vdc}{Vref} ) + {A}_{o}$$

Where: Vref is the reference voltage for the ADC converter.

With this, the exact voltage level of each DC test signal Vdc is known as a function of the reference voltage for the ADC circuit and can be used by the test and calibration circuit 52 for determining the actual characteristic coefficient CC_{act} of the power detector circuit 30.

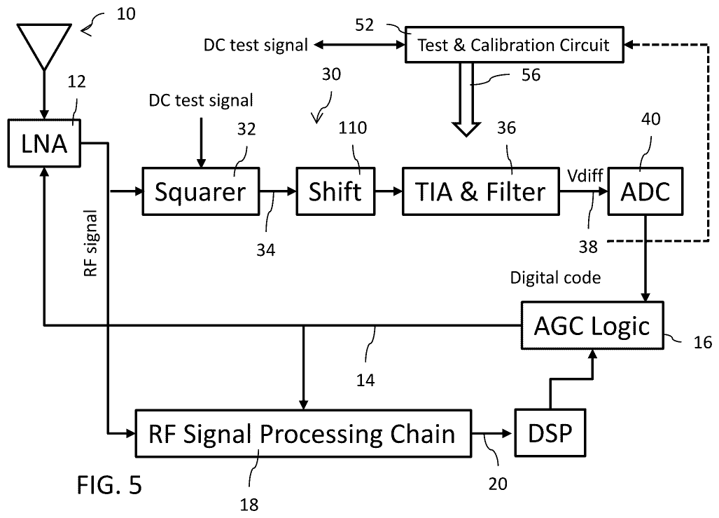

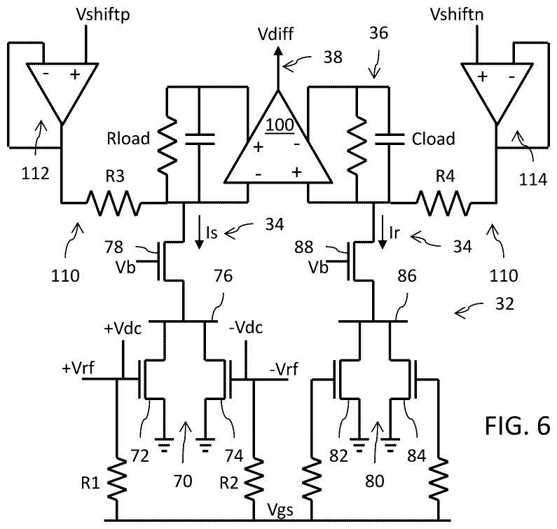

Reference is made to FIG. 5 where like references refer to same or similar components as shown in FIG. 3. The implementation of FIG. 5 differs from the implementation of FIG. 3 in the further inclusion of a shifting circuit 110 coupled to the differential output of the squarer circuit 32. FIG. 6 shows a circuit diagram for an implementation of the shifting circuit 110. Like references in FIGS. 4 and 6 refer to same or similar components for the squarer circuit 32 and TIA circuit 36.

The shifting circuit 110 includes a first voltage shifter coupled to the sensing branch of the squarer circuit 32 at the drain of the third MOSFET device 78 (inverting input of the amplifier 100). The first voltage shifter includes a differential amplifier 112 having an output coupled to the sensing branch through a resistor R3. A non-inverting input of the amplifier 112 receives a first shift voltage Vshiftp, and the inverting input of the amplifier 112 is coupled in feedback to the output of the amplifier 112.

The shifting circuit 110 includes a second voltage shifter coupled to the reference branch of the squarer circuit 32 at the drain of the sixth MOSFET device 88 (non-inverting input of the amplifier 100). The second voltage shifter includes a differential amplifier 114 having an output coupled to the reference branch through a resistor R4. A non-inverting input of the amplifier 114 receives a second shift voltage Vshiftn, and the inverting input of the amplifier 114 is coupled in feedback to the output of the amplifier 114.

The resistors Rload, R3 and R4 preferably have a same resistance.

The voltage Vshiftp is selected to be higher than the common mode voltage of the amplifier 100 and less than the supply voltage. The voltage Vshiftn is selected to be lower than the common mode voltage of the amplifier 100 and higher than the ground voltage.

The shift effectuated by the shifting circuit 110 serves to shift the dynamic range of the output voltage Vdiff to match the dynamic range of the ADC circuit 40.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A root mean square (RMS) power detector circuit, comprising:
a first input configured to receive a radio frequency (RF) signal;
a second input configured to receive a gate bias signal;
a third input configured to receive a direct current (DC) test signal;
a squarer circuit comprising a MOSFET device with a gate, a source and a drain;
wherein, in a normal operating mode, the RF signal and the gate bias signal are applied to the gate of the MOSFET device and a drain current at the drain of the MOSFET device is indicative of power of the RF signal; and
wherein, in a calibration mode, the DC test signal and the gate bias signal are applied to the gate of the MOSFET device and the drain current at the drain of the MOSFET device is indicative of power of the DC test signal.

2. The RMS power detector circuit of claim 1, further comprising:
a transimpedance amplifier (TIA) circuit configured to convert the drain current to an analog voltage; and
an analog to digital converter (ADC) circuit configured to convert the analog voltage to a digital code.

3. The RMS power detector circuit of claim 2, where the TIA circuit includes a low pass filter configured to filter out, from the drain current, fundamental and harmonic frequency components of the RF signal above a filter cut-off frequency.

4. The RMS power detector circuit of claim 2, further comprising a shifting circuit configured to apply a shift voltage to the drain current, wherein the shift voltage adjusts the analog voltage output from the TIA circuit to match a dynamic range of the ADC circuit.

5. The RMS power detector circuit of claim 1, further comprising a calibration circuit configured to process the digital code output by the ADC circuit select to calculate a characteristic coefficient of the RMS power detector circuit.

6. The RMS power detector circuit of claim 5, wherein the calibration circuit is further configured to apply at least two distinct DC voltage levels for the DC test signal during calibration mode, and further process digital codes output by the ADC circuit in response to said at least two distinct DC voltage levels for the DC test signal to compensate for offset in the RMS power detector circuit.

7. The RMS power detector circuit of claim 5, further comprising a resistor network configured to apply the gate bias signal, wherein the calibration circuit is further configured to apply at least three distinct DC voltage levels for the DC test signal during calibration mode, and further process digital codes output by the ADC circuit in response to said at least three distinct DC voltage levels for the DC test signal to compensate for offset in the RMS power detector circuit and compensate for resistance mismatch in the resistor network.

8. A radio frequency (RF) receiver, comprising:
a low noise amplifier (LNA) circuit coupled to an antenna;
an RF signal processing chain coupled to receive an RF signal output from the LNA circuit;
an automatic gain control (AGC) circuit configured to control signaling for controlling gain at the LNA circuit and in the RF signal processing chain in response to a digital code indicative of RF power;
a power detector circuit coupled to receive then RF signal output from the LNA circuit, wherein the power detector circuit comprises:
a squarer circuit comprising a MOSFET device with a gate, a source and a drain;
wherein, in a normal operating mode, the RF signal and a gate bias signal are applied to the gate of the MOSFET device and a drain current at the drain of the MOSFET device is indicative of power of the RF signal;
wherein, in a calibration mode, a DC test signal and the gate bias signal are applied to the gate of the MOSFET device and the drain current at the drain of the MOSFET device is indicative of power of the DC test signal;
a transimpedance amplifier (TIA) circuit configured to convert the drain current to an analog voltage; and
an analog to digital converter (ADC) circuit configured to convert the analog voltage to the digital code for input to the AGC circuit.

9. The RF receiver of claim 8, where the TIA circuit includes a low pass filter configured to filter out, from the drain current, fundamental and harmonic frequency components of the RF signal above a filter cut-off frequency.

10. The RF receiver of claim 8, further comprising a shifting circuit configured to apply a shift voltage to the drain current, wherein the shift voltage adjusts the analog voltage output from the TIA circuit to match a dynamic range of the ADC circuit.

11. The RF receiver of claim 8, further comprising a calibration circuit configured to process the digital code output by the ADC circuit to calculate a characteristic coefficient of the RMS power detector circuit.

12. The RF receiver of claim 11, wherein the calibration circuit is further configured to select at least two distinct DC voltage levels for the DC test signal during calibration mode, and further process digital codes output by the ADC circuit in response to said at least two distinct DC voltage levels to compensate for offset in the RMS power detector circuit.

13. The RF receiver of claim 11, further comprising a resistor network configured to apply the gate bias signal, wherein the calibration circuit is further configured to select at least three distinct DC voltage levels for the DC test signal during calibration mode, and further process digital codes output by the ADC circuit in response to said at least three distinct DC voltage levels to compensate for offset in the RMS power detector circuit and compensate for resistance mismatch in the resistor network.

14. A method, comprising:
in a normal operating mode, applying an RF signal and a gate bias signal to a gate of a MOSFET device within a root mean square (RMS) power detector circuit and generating a drain current indicative of power of the RF signal; and
in a calibration mode, applying a DC test signal and the gate bias signal to the gate of the MOSFET device and generating the drain current indicative of power of the DC test signal.

15. The method of claim 14, further comprising:
converting the drain current to an analog voltage; and
converting the analog voltage to a digital code.

16. The method of claim 15, further comprising low pass filtering the drain current to remove fundamental and harmonic frequency components of the RF signal above a filter cut-off frequency.

17. The method of claim 15, further comprising a shifting the analog voltage to match a dynamic range of an analog to digital (ADC) circuit which performs the conversion of the analog voltage to the digital code.

18. The method of claim 14, further comprising processing the digital code output by the ADC circuit to calculate a characteristic coefficient of the RMS power detector circuit.

19. The method of claim 18, further comprising: selecting at least two distinct DC voltage levels for the DC test signal during calibration mode, and processing digital codes output by the ADC circuit in response to said at least two distinct DC voltage levels for the DC test signal to compensate for offset in the RMS power detector circuit.

20. The method of claim 18, further comprising: selecting at least three distinct DC voltage levels for the DC test signal during calibration mode, and processing digital codes output by the ADC circuit in response to said at least three distinct DC voltage levels for the DC test signal to compensate for offset in the RMS power detector circuit and compensate for resistance mismatch present in a biasing circuit configured to generate the gate bias signal.

21. A power detector circuit, comprising:
a squarer circuit, comprising:
a first differential pair of MOSFET devices having gate terminals biased by a gate bias signal and configured to receive an input signal, said first differential pair of MOSFET devices configured to generate a sensing current indicative of power of the input signal; and
a second differential pair of MOSFET devices having gate terminals biased by the gate bias signal, said second differential pair of MOSFET devices configured to generate a reference current;
wherein, in a normal operating mode, the input signal is an RF signal; and
wherein, in a calibration operating mode, the input signal is a DC test signal;
a transimpedance amplifier circuit configured to convert a difference between the sensing current and the reference current to an analog voltage; and
an analog to digital converter circuit configured to convert the analog voltage to a digital code indicative of power of the RF signal, when in the normal operating mode, and indicative of power of the DC test signal, when in the calibration operating mode.

22. The circuit of claim 21, wherein the transimpedance amplifier circuit includes a low pass filter circuit configured to filter the difference between the sensing current and the reference current to remove fundamental and harmonic frequency components of the RF signal above a filter cut-off frequency.

23. The circuit of claim 21, further comprising a calibration circuit configured to process the digital code output by the analog to digital converter circuit, when in the calibration operating mode, to calculate a characteristic coefficient of the power detector circuit.

24. The circuit of claim 23, wherein the calibration circuit is configured to process digital codes output by the analog to digital converter circuit, when in the calibration operating mode, to compensate for offset in the power detector circuit.

25. The circuit of claim 23, wherein the squarer circuit further comprises a resistor network configured to apply the gate bias signal to the gate terminals of the first differential pair of MOSFET devices, and wherein the calibration circuit is configured to process digital codes output by the analog to digital converter circuit, when in the calibration operating mode, to compensate for resistance mismatch in the resistor network.
